(19) United States
(12) Patent Application Publication
(10) Pub. No.: US 2011/0180142 A1
(43) Pub. Date: Jul. 28, 2011

(54) ELECTRICAL AND OPTICAL PROPERTIES OF SILICON SOLAR CELLS

(75) Inventors: Stefano Benagli, Neuchatel (CH); Johannes Meier, Corcelles (CH); Ulrich Kroll, Corcelles (CH)

(73) Assignee: OERLIKON SOLAR AG, TRUEBBACH, Truebbach (CH)

(21) Appl. No.: 13/059,685

(22) PCT Filed: Aug. 6, 2009
(86) PCT No.: PCT/EP09/60200

§ 371 Date: Feb. 18, 2011

Related U.S. Application Data
(60) Provisional application No. 61/089,931, filed on Aug. 19, 2008.

(51) Int. Cl. H01L 31/0376; H01L 31/18

(52) U.S. Cl. 136/258; 438/96; 257/E31.047

(57) ABSTRACT

The method for manufacturing a photovoltaic cell or a photovoltaic converter panel comprises depositing a layer of p-doped amorphous silicon using a gas mixture comprising silane, methane, hydrogen and trimethylboron in a ratio of 1:2:2:1.25. In particular, plasma-enhanced chemical vapor deposition is used for the deposition. The corresponding photovoltaic cells and photovoltaic converter panels are also described.

This invention relates to improvements resulting in improvements of the efficiency of thin-film solar cell technology.

### FIELD OF THE INVENTION

Photovoltaic solar energy conversion offers the perspective to provide for an environmentally friendly means to generate electricity. However, at the present state, electric energy provided by photovoltaic energy conversion units is still significantly more expensive than electricity provided by conventional power stations. Therefore, the development of more cost-effective means of producing photovoltaic energy conversion units attracted attention in the recent years. Amongst different approaches of producing low-cost solar cells, thin film silicon solar cells combine several advantageous aspects: firstly, thin-film silicon solar cells can be prepared by known thin-film deposition techniques such as plasma enhanced chemical vapor deposition (PECVD) and thus offer the perspective of synergies to reduce manufacturing cost by using experiences achieved in the past for example on the field of other thin film deposition technologies such as the displays sector. Secondly, thin-film silicon solar cells can achieve high energy conversion efficiencies striving for 10% and beyond. Thirdly, the main raw materials for the production of thin-film silicon based solar cells are abundant and non-toxic.

A thin-film solar cell generally includes a first electrode, one or more semiconductor thin-film p-i-n or n-i-p junctions, and a second electrode, which are successively stacked on a substrate. Each p-i-n junction or thin-film photoelectric conversion unit includes an i-type layer sandwiched between a p-type layer and an n-type layer (p-type=positively doped, n-type=negatively doped). The i-type layer, which is a substantially intrinsic semiconductor layer, occupies the predominant part of the thickness of the thin-film p-i-n junction. Photoelectric conversion occurs primarily in this i-type layer.

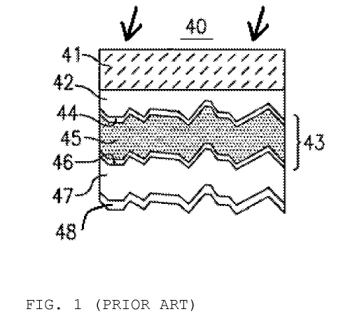

Prior Art FIG. 1 shows a basic, simple photovoltaic cell 40 comprising a transparent substrate 41, e.g. glass with a layer of a transparent conductive oxide (TCO) 42 deposited thereon. This layer is also called front contact FC and acts as first electrode for the photovoltaic element. The next layer 43 acts as the active photovoltaic layer and comprises three “sub-layers” forming a p-i-n junction. Said layer 43 comprises hydrogenated microcrystalline, nanocrystalline or amorphous silicon or a combination thereof. Sub-layer 44 adjacent to TCO front contact 42 is positively doped, the adjacent sub-layer 45 is intrinsic, and the final sub-layer 46 is negatively doped. In an alternative embodiment the layer sequence p-i-n as described can be inverted to n-i-p, then layer 44 is identified as n-layer, layer 45 again as intrinsic, layer 46 as p-layer.

Finally, the cell includes a rear contact layer 47 (also called back contact, BC) which may be made of zinc oxide, tin oxide or ITO and a reflective layer 48. Alternatively a metallic back contact may be realized, which can combine the physical properties of back reflector 48 and back contact 47. For illustrative purposes, arrows indicate impinging light.

### BACKGROUND OF THE INVENTION

An amorphous silicon solar cells device comprises a p-layer (doped positively) used in combination with a n-layer (doped negatively) to build an electric field within a silicon i-layer (intrinsic material), which is in-between the two doped layers. For p-i-n devices as known in the art light firstly passes through a substrate, then the p-layer, next the i-layer and finally the n-layer. As the light absorbed in the p-layer does not contribute to the electric current of the device, this layer should be as transparent as possible. The easiest way to gain in transparency is to reduce the thickness. However, a certain minimal thickness is necessary to build the electric field across the i-layer. Indeed the electric field is directly related to the conductivity of the doped layers. Hence, in p-i-n devices the p-layer should be optimized as transparent and as conductive as possible. Usually transparency is obtained by alloying the p-layer with O, C, H, etc.

### RELATED ART

P. Lechner et al., MRS Symposium records, Vol 192 (1990) p. 81 ff describes that hydrogenated amorphous SiC:H films have been prepared by RF glow discharge from a silane-methane mixture, with a B-doping either from diborane or trimethylborone (TMB).

### BRIEF DESCRIPTION OF THE DRAWINGS

Prior Art FIG. 1 shows the basic configuration of thin-film silicon solar cell.

### SUMMARY OF THE INVENTION

Usually, highly conductive p-layers show a reduced transmission compared to layers with lower conductivity. Optimizing the conductivity and the transmission at the same time is crucial for obtaining devices with high efficiencies. The invention, as taught in more detail below addresses this problem.

### DETAILED DESCRIPTION OF THE INVENTION

The solution is to combine the properties of high transmission and good conductivity (σ) in a single material for a p-layer. The transmission of a layer is related to its absorption coefficient (α), and this relation is dependent on the wavelength of light. The optimal range for high efficiencies devices is given by formula (1).

1<log(α(400 nm))−log((σ(S/cm))<13 Formula (1)

Preferred: 6<log(α(400 nm))−log((σ(S/cm))<9

Using doped layers in silicon solar cell structures in this range leads to devices with optimal performances.

When methane (CH₄) is added to the gas mixture for a p-layer (for instance composed by SiH₄, H₂ and TMB (trimethylboron)) the transparency of the material increases. A careful tuning of the gas mixture results in p-layers with an absorption coefficient and conductivity as in formula (1). Typically the gas mixture is as on table 1. In order to increase the transparency it is possible to use as well other alloys with carbon, oxygen or nitrogen and for the doping it can be used boron, aluminum, gallium, indium or thallium.

TABLE 1
Gas mixture for a-Si:H p-layer with low absorption and good
conductivity.

| SiH₄ | CH₄ | H₂ | TMB |
|---|---|---|---|
| 1 | 2 | 2 | 1.25 |

Adding CH₄ in the p-layer (as listed in table 1) results in a device with an increased short-circuit current density (J_{sc}) compared to a standard p-layer without CH₄. Typical cell parameters are listed in table 2.

TABLE 2
Cell (1 cm²) normalized electrical parameters for two
different p-layers. I-V measurements were done with a Wacom solar
simulator.

| | J_{sc} | V_{oc} | FF | efficiency |
|---|---|---|---|---|
| Standard p | 1 | 1 | 1 | 1 |
| p with CH4 | 1.03 | 1 | 1 | 1.03 |

While the invention has been described with a view on amorphous silicon p-layers, it is not limited to that. The presented p-layer could be used as well in mircromorph tandem junction devices or in triple junction devices, and this in the p-i-n and n-i-p configuration.

In particular, the invention comprises the following embodiments and aspects:

A method for manufacturing a photovoltaic cell or a photovoltaic converter panel, comprising the step of depositing a layer of p-doped amorphous silicon, more particularly of amorphous hydrogenated silicon, using a gas mixture comprising silane, methane, hydrogen and trimethylboron in a ratio of 1:2:2:1.25, each within ±15%, more particularly each within ±10%. Even more particularly, said gas mixture substantially consists of silane, methane, hydrogen and trimethylboron in said ratio of substantially 1:2:2:1.25, each within ±15% or more particularly each within ±10%. In another particular embodiment, said gas mixture comprises silane, methane, hydrogen and trimethylboron in a ratio of substantially 1:2:2:1.25, and more particularly, said gas mixture substantially consists of silane, methane, hydrogen and trimethylboron in a ratio of substantially 1:2:2:1.25. In one embodiment, said depositing is carried out using a thin-film deposition process; more particularly, said depositing is carried out in a plasma-enhanced chemical vapor deposition process. Typically, said layer is a layer of a p-i-n or a n-i-p junction of the photovoltaic cell or photovoltaic converter panel.

In one embodiment, the method comprises after said deposition step the steps of
depositing a thin-film layer of substantially intrinsic silicon, more particularly of substantially intrinsic hydrogenated silicon, and thereafter
depositing a thin-film layer of n-doped silicon, more particularly of n-doped hydrogenated silicon,
   or comprising before said deposition step the steps of
depositing a thin-film layer of n-doped silicon, more particularly of n-doped hydrogenated silicon, and thereafter
depositing a thin-film layer of substantially intrinsic silicon, more particularly of substantially intrinsic hydrogenated silicon.

In one embodiment, the photovoltaic cell or photovoltaic converter panel is a single-junction device.

In one embodiment, the photovoltaic cell or photovoltaic converter panel is a micromorph tandem junction device.

In one embodiment, the photovoltaic cell or photovoltaic converter panel is a triple junction device.

In one aspect, the invention comprises a use, namely a use of a gas mixture comprising (and, more particularly, substantially consisting of) silane, methane, hydrogen and trimethylboron in a ratio of 1:2:2:1.25, each within ±15%, more particularly each within ±10% for depositing a layer of p-doped amorphous silicon as a portion of a p-i-n or n-i-p junction of a photovoltaic cell or a photovoltaic converter panel. In particular, wherein said gas mixture comprises (and, more particularly, substantially consists of) silane, methane, hydrogen and trimethylboron in a ratio of substantially 1:2:2:1.25.

In one aspect, the invention comprises a photovoltaic cell comprising at least one layer of p-doped amorphous silicon, more particularly of amorphous hydrogenated silicon, as obtainable, more particularly as obtained, in a deposition process using a gas mixture comprising silane, methane, hydrogen and trimethylboron in a ratio of 1:2:2:1.25, each within ±15%, more particularly each within ±10%. Even more particularly, said gas mixture comprises silane, methane, hydrogen and trimethylboron in a ratio of substantially 1:2:2:1.25. In a more specific embodiment, said gas mixture substantially consists of silane, methane, hydrogen and trimethylboron in a ratio of 1:2:2:1.25, each within ±15%, and more particularly, wherein said gas mixture substantially consists of silane, methane, hydrogen and trimethylboron in a ratio of substantially 1:2:2:1.25.

In one embodiment, said deposition process is a thin-film deposition process, more particularly a plasma-enhanced chemical vapor deposition process.

The photovoltaic cell can specifically be a thin-film silicon cell with one p-i-n or n-i-p junction, or a micromorph tandem junction device or a triple junction device.

The photovoltaic converter panel comprises at least one photovoltaic cell described above.

The invention comprises uses and devices with corresponding features of corresponding methods and vice versa; their respective advantages correspond to each other.

1. Method for manufacturing a photovoltaic cell or a photovoltaic converter panel, comprising the step of depositing a layer of p-doped amorphous silicon, more particularly of amorphous hydrogenated silicon, using a gas mixture comprising silane, methane, hydrogen and trimethylboron in a ratio of 1:2:2:1.25, each within ±15%.

2. The method of claim 1, wherein said gas mixture substantially consists of silane, methane, hydrogen and trimethylboron in said ratio of 1:2:2:1.25, each within ±15%.

3. The method of claim 1 or claim 2, wherein said ratio is substantially 1:2:2:1.25.

4. The method of one of the preceding claims, wherein said depositing is carried out using a thin-film deposition process.

5. The method of one of the preceding claims, wherein said depositing is carried out in a plasma-enhanced chemical vapor deposition process.

6. The method of one of the preceding claims, wherein said layer is a layer of a p-i-n or a n-i-p junction of the photovoltaic cell or the photovoltaic converter panel.

7. The method of one of the preceding claims, comprising after said deposition step the steps of depositing a thin-film layer of substantially intrinsic silicon, more particularly of substantially intrinsic hydrogenated silicon, and thereafter depositing a thin-film layer of n-doped silicon, more particularly of n-doped hydrogenated silicon, or comprising before said deposition step the steps of depositing a thin-film layer of n-doped silicon, more particularly of n-doped hydrogenated silicon, and thereafter depositing a thin-film layer of substantially intrinsic silicon, more particularly of substantially intrinsic hydrogenated silicon.

8. The method of one of the preceding claims, wherein the photovoltaic cell or photovoltaic converter panel is a single-junction device or a micromorph tandem junction device or a triple junction device.

9. Use of a gas mixture comprising silane, methane, hydrogen and trimethylboron in a ratio of 1:2:2:1.25, each within ±15%, for depositing a layer of p-doped amorphous silicon as a portion of a p-i-n or n-i-p junction of a photovoltaic cell or a photovoltaic converter panel.

10. The use of claim 9, wherein said gas mixture substantially consists of silane, methane, hydrogen and trimethylboron in a ratio of 1:2:2:1.25, each within ±15.

11. Photovoltaic cell comprising at least one layer of p-doped amorphous silicon, more particularly of amorphous hydrogenated silicon, as obtainable in a deposition process using a gas mixture comprising silane, methane, hydrogen and trimethylboron in a ratio of 1:2:2:1.25, each within ±15%.

12. The photovolaic cell of claim 11, wherein said gas mixture comprises silane, methane, hydrogen and trimethylboron in a ratio of substantially 1:2:2:1.25.

13. The photovolaic cell of claim 11 or claim 12, wherein said deposition process is a thin-film deposition process, more particularly a plasma-enhanced chemical vapor deposition process.

14. The photovolaic cell of one of claims 11 to 13, wherein the photovoltaic cell is a thin-film silicon cell with one p-i-n or n-i-p junction, or a micromorph tandem junction device or a triple junction device.

15. A photovoltaic converter panel comprising at least one photovoltaic cell according to one of claims 11 to 14.
